(19) United States
(12) Patent Application Publication
(10) Pub. No.: US 2009/0212286 A1
(43) Pub. Date: Aug. 27, 2009

(54) METHOD FOR MAKING AMORPHOUS POLYCRYSTALLINE SILICON THIN-FILM CIRCUITS

(75) Inventor: Walid Benzarti, Montrouge (FR)

Correspondence Address: LOWE HAUPTMAN & BERNER, LLP, 1700 DIAGONAL ROAD, SUITE 300, ALEXANDRIA, VA, 22314, US

(73) Assignee: Commissariat A L'Energie Atomique, Paris (FR)

(21) Appl. No.: 12/064,475

(22) PCT Filed: Aug. 29, 2006
(86) PCT No.: PCT/EP2006/065769

§ 371 Date: Oct. 8, 2008

(30) Foreign Application Priority Data
Aug. 30, 2005 (FR) 0508878

(51) Int. Cl. H01L 29/786; H01L 21/336

(52) U.S. Cl. 257/57; 438/164; 257/E21.412; 257/E29.288

(57) ABSTRACT

The invention relates to the fabrication of thin-film transistors made of amorphous silicon and of polycrystalline silicon on one and the same substrate. A polycrystalline silicon island (12) is formed, an insulating layer (14) and a first conducting layer (16) are deposited and these two layers are etched to the same pattern so as to simultaneously define a first insulated gate on top of the island and a second gate away from the island. The polycrystalline silicon is doped in order to form the source and the drain of a polycrystalline silicon first transistor (gate above the channel). An insulating layer (18) forming the gate insulator of an amorphous silicon transistor (gate beneath the channel) is deposited. The fabrication of the amorphous silicon transistor then continues with the deposition and etching of undoped amorphous silicon (20) and doped silicon (22), etching of the insulating layer (18) and deposition and etching of interconnect metal (28). The invention is applicable to LCD, LED and OLED.

### CROSS-REFERENCE TO RELATED APPLICATIONS

The present Application is based on International Application No. PCT/EP2006/065769, filed on Aug. 29, 2006, which in turn corresponds to French Application No. 05 08878, filed on Aug. 30, 2005 and priority is hereby claimed under 35 USC §119 based on these applications. Each of these applications are hereby incorporated by reference in their entirety into the present application.

### FIELD OF THE INVENTION

The invention relates to the fabrication of electrical circuits based on TFTs (thin-film transistors), such as those used for example for active-matrix flat-panel displays (liquid crystal or organic light-emitting diode displays).

### BACKGROUND OF THE INVENTION

These displays generally use amorphous silicon transistors, which are simple and inexpensive to produce. The transistors are produced in general using the “bottom gate” technique, that is to say the gate of the transistor is located beneath the channel between source and drain. The fabrication process uses few (3 or 4) masks; it is completely controlled and there are few defects; the threshold voltage of the transistors is spatially quite uniform (from one transistor to another on the same wafer); and the leakage currents of the transistor in the off-state are low.

However, this technology has a few drawbacks, in particular, the excessively low electron mobility in amorphous silicon, the high overlap capacitance between gate and drain, the high overlap capacitance between gate and source, the variation in threshold voltage during operation of the transistor (aging by degradation of the gate insulator), and finally the impossibility of making pMOS transistors (excessively low mobility of the hole carriers in amorphous silicon). The above drawbacks make these transistors difficult to use in certain operations in displays, notably the drive functions, but also the current switching function within the pixel for light-emitting diode displays.

Another technology approach consists in producing transistors from polycrystalline silicon, which is laser-recrystallized amorphous silicon, with the gate on top of the channel (“top gate” technology). This technology allows the source and drain to be aligned with the gate and therefore gives lower overlap capacitances. It makes it possible to produce pMOS transistors just as well as nMOS transistors. The electron mobility in polycrystalline silicon is higher than in amorphous silicon. The threshold voltage is stable during operation.

However, the number of masks is higher than in the case of amorphous silicon transistors; the threshold voltages of the transistors are spatially more dispersed, because of the variable grain size of polycrystal grains, and the leakage current of the transistors in the off-state is higher.

The advantages and disadvantages of these two types of technology are to a certain extent complementary and it may be desirable to have both types of transistor on one and the same substrate.

To give an example, in the case of a liquid crystal display, it may be desirable to use polycrystalline silicon transistors for the matrix addressing circuits, and above all for the high-current amplifiers or drivers that drive the rows. They must be able to operate at high current (required for high electron mobility) and at high frequency (required for low overlap capacitances). In addition, it is advantageous for the logic circuits for driving the matrix to use pMOS and nMOS complementary transistors for consumption reasons. Polycrystalline silicon transistors lend themselves very well to this use.

Conversely, the transistor that maintains the charge at the terminals of a storage capacitor in an individual pixel ought preferably to be an amorphous silicon transistor. This is because the leakage current is lower and the charge stored may be better contained over the duration of a frame. Moreover, as the charge is better maintained it is possible to use a capacitor of smaller size to store this charge; consequently, since the storage capacitor uses space to the detriment of the electrodes that define the image, the open aperture ratio of the pixels may be better. Finally, since the capacitance of the liquid crystal is low, the gate/source or gate/drain overlap capacitance of the amorphous silicon transistor does not penalize the transient operation of the pixel.

This is why it has been attempted to produce, on one and the same substrate, both amorphous silicon transistors and polycrystalline silicon transistors so that the amorphous silicon transistors are used for the functions where they are more advantageous and the polycrystalline silicon transistors are used for the functions where amorphous silicon transistors are less advantageous.

U.S. Pat. No. 5,864,150, patent JP 2002185005 and the article IEEE Transactions on Electron Devices, Vol. 43, No. 5, May 1995 describe amorphous/polycrystalline hybrid technologies. However, these technologies have the drawback of resulting in poorly optimized transistors, notably from the fact that the polycrystalline silicon transistors are all “bottom gate” transistors, with the gate beneath the channel, whereas they would have better performance if they were produced as “top gate” transistors, with the gate above the channel.

### SUMMARY OF THE INVENTION

The object of the invention is to provide a process for fabricating thin-film transistors (TFTs) which makes it possible, with a particularly small number of masks, to produce both “bottom gate” amorphous silicon transistors and “top gate” polycrystalline silicon transistors on the same substrate.

The invention therefore provides a process for fabricating thin-film transistors made of amorphous silicon and polycrystalline silicon on one and the same substrate, characterized in that: a polycrystalline silicon island corresponding to a polycrystalline silicon transistor is firstly formed on the substrate; then a first electrically insulating layer and a first conducting layer are deposited; these two layers are etched to the same pattern so as to simultaneously define, in the conducting layer, a first insulated gate on top of the island and a second gate away from the island; a second insulating layer is deposited, which forms a passivation layer on top of the first insulated gate and forms the gate insulator on top of the second gate; and then the fabrication of the amorphous silicon transistor then continues with steps comprising, among others, the deposition of intrinsic amorphous silicon in order to constitute the channel of the amorphous silicon transistor on top of the second gate, the deposition of doped amorphous silicon in contact with the intrinsic amorphous silicon everywhere the latter is present, in order to define a source and a drain on either side of this channel of the amorphous silicon transistor, the deposition on the doped amorphous silicon layer of a second conducting layer with contacts on the sources and drains of the various transistors, the etching of the second conducting layer and the removal of the subjacent doped amorphous silicon layer, where the latter has not been protected by the second conducting layer, using a selective etchant that hardly etches the intrinsic amorphous silicon.

In other words, an important feature of the fabrication process according to the invention is that a polycrystalline silicon island is firstly formed with an insulated gate on top of the channel and, with the same conducting gate layer, the gate of an amorphous silicon transistor with a gate beneath the channel is formed before an insulator is deposited that will form both the passivation layer for the transistor with the gate above the channel and gate-channel insulation of the transistor with a gate beneath the channel.

The term “intrinsic silicon” is understood to mean silicon that is not intentionally doped, or else is lightly doped. The source and the drain are in both cases more highly doped than the channel.

An etch mask is used to define the conducting interconnects. Once the interconnects are defined, they serve as masks for removing the more doped amorphous silicon at the point where it is not protected by an interconnect. The etching used is selective etching so as not to significantly etch the intrinsic amorphous silicon layer that serves as channel.

This results in a novel thin-film circuit comprising, on one and the same substrate, at least two thin-film transistors, one of which is a polycrystalline silicon transistor with a gate above the channel and the other is an amorphous silicon transistor with a gate beneath the channel, the gates of the two transistors being formed by two portions of one and the same conducting layer, one being deposited on top of a polycrystalline silicon island, from which it is separated by a first electrically insulating layer portion, and the other portion being deposited on top of the substrate, from which it is separated by a second portion of the same insulating layer.

If the main steps of the fabrication process according to the invention are explained in more detail, the following operations are involved:

a) formation of a polycrystalline silicon layer on the substrate and etching of this layer to leave behind at least one island corresponding to a polycrystalline transistor;

b) deposition of a first electrically insulating layer and a first conducting layer;

c) etching of the conducting layer and of the first insulating layer so as to leave behind at least one polycrystalline transistor gate on top of the island and at least one gate of an amorphous transistor away from the island;

d) deposition of a second insulating layer constituting the gate insulator of the amorphous transistor;

e) a group of operations which comprise: at least the deposition of an intrinsic amorphous silicon layer; the etching of this layer in a zone extending beyond either side of the gate of the amorphous transistor; the deposition of doped amorphous silicon in contact with the amorphous silicon layer everywhere it is present; and the opening of vias right through the thickness of the second insulating layer;

f) deposition of a second conducting layer, in principle a metal layer, and etching of this layer to define interconnects and source and drain contacts on either side of a channel zone above the gate of the amorphous transistor, and also source and drain contacts on either side of a channel zone beneath the gate of the polycrystalline silicon transistor; and

g) removal of the doped amorphous silicon layer at the point where the latter has not been protected by the second conducting layer.

With this process, it is possible to produce both a polycrystalline silicon transistor with a gate above the channel and an amorphous silicon transistor with a gate beneath the channel, with a very small number of masking steps. At the same time, it is possible to define capacitors in which the electrodes are superposed portions of the first and second conducting layers and the dielectric of which is a portion of the second insulating layer.

The initial deposition of polycrystalline silicon is in principle carried out as follows: deposition of intrinsic amorphous silicon followed by laser recrystallization.

Preferably, after the gate of the polycrystalline silicon transistor has been formed (i.e. after step c), an ion implantation of impurities corresponding to the type of transistor—nMOS or pMOS—to be produced is carried out.

In a first method of implementation, in step e, intrinsic amorphous silicon is firstly deposited, then the deposition of the doped amorphous silicon layer is carried out, and then these two layers are etched in one and the same pattern defining an island corresponding to the amorphous transistor, and finally the vias are etched in the second insulating layer.

In a second method of implementation, in step e, first of all the vias are etched in the second insulating layer, a layer of intrinsic amorphous silicon is then deposited, this layer is then etched and then doped amorphous silicon and a conducting layer are deposited, and these two layers are etched in one and the same pattern defining the interconnects.

In a third method of implementation, in step e, the intrinsic amorphous silicon is firstly deposited, doped amorphous silicon is then deposited, and then these two layers and the insulating layer are etched so as to open vias.

The invention is particularly applicable to a liquid crystal display or a light-emitting diode display, the amorphous silicon transistors of which constitute an active element of each pixel and the polycrystalline silicon transistors of which serve for controlling the rows of the display. Each pixel may comprise not only an amorphous silicon transistor serving to apply and then maintain an electrical charge on a storage capacitor, but also a polycrystalline silicon transistor serving for example to ensure that a constant current passes into a light-emitting diode associated with this pixel.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIGS. 1 to 4 show the first steps of the fabrication process according to the invention;

FIGS. 5 to 9 show the sequence of operations in a first implementation variant;

FIGS. 10 to 14 show the sequence of FIGS. 1 to 4 in a second implementation variant; and

FIGS. 15 to 17 show the operations that follow FIG. 5 in a third implementation variant.

### DETAILED DESCRIPTION OF THE DRAWINGS

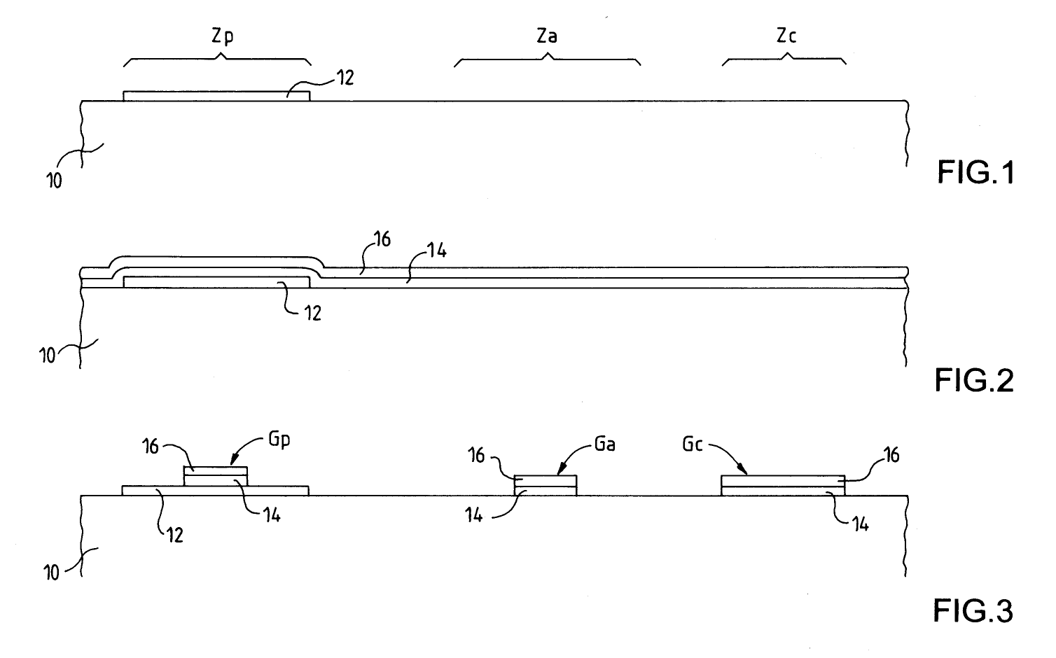

The essential steps of the fabrication process that are common to the different variants will firstly be described with reference to FIGS. 1 to 4.

FIG. 1 shows the substrate 10 of a display on which the aim is to produce at least three types of element, these being a polycrystalline silicon transistor in a zone Zp of the substrate, an amorphous silicon transistor in a zone Za, and a capacitor in a zone Zc, respectively.

The substrate 10 will in general be made of glass, but it may also be made of plastic, stainless steel, silicon, etc. It is preferably covered, prior to any other operation, with a buffer layer (having a planarization and/or physicochemical barrier function) for example made of silicon oxide (this layer is not shown).

A layer of silicon is deposited uniformly on the substrate, which layer will serve for the fabrication of the polycrystalline silicon transistor and is etched so as to leave behind a silicon island 12 in the zone Zp but not in the zones Za and Zc. Preferably, the silicon is firstly deposited in amorphous form, for example with a thickness of about 80 nanometers. It is then crystallized using a laser and takes the form of polycrystalline silicon. It is then etched through a first mask to the shape of the desired island (FIG. 1). The silicon is lightly or very lightly doped, or even quasi-intrinsic.

A first insulating layer 14 is then uniformly deposited on the substrate, which layer will serve as gate insulator for the polycrystalline silicon transistor (FIG. 2). The layer 14 may be made of silicon oxide with a thickness of about 100 nanometers. Next, a first conducting layer 16, preferably a metal layer, is deposited, which will constitute the gate of the amorphous silicon transistor, and also the gate of the polycrystalline silicon transistor. The layer 16 may be made of aluminum with a thickness of about 200 nanometers.

The first conducting layer 16 is etched through a second mask, which defines, simultaneously:

a gate Gp of the polycrystalline silicon transistor in the zone Zp, above the island 12 and isolated from the island by the oxide layer 14, the island extending beyond either side of this gate;

a gate Ga of the amorphous silicon transistor away from this island, in the zone Za; and

a lower capacitor electrode Gc in the zone Zc, which electrode will also be called hereafter “gate” to simplify matters when the three gates Gp, Ga and Gc are referred to collectively.

Next, the first insulating layer 14 is removed by selective chemical etching at the points where it is no longer protected by the gate features.

What are obtained are gate features Gp, Ga, Gc produced in the same aluminum layer 16 (FIG. 3), the gate Gp being isolated from the polycrystalline silicon by a gate insulator consisting of a portion of the silicon oxide layer 14.

The process then continues with the formation of the source and drain of the polycrystalline silicon transistor, by doping the island 12 at the point where it is not protected by the gate Gp. The doping is preferably performed by ion implantation. The implanted impurity is of n type if it is desired to produce nMOS transistors, or of p type if it is desired to produce pMOS transistors. If it is desired to produce an nMOS transistor on a polycrystalline silicon island and a pMOS transistor on this island or on another island, an additional mask is required to mask the pMOS transistors during n-type implantation, and then to mask the nMOS transistors during p-type implantation.

The polycrystalline silicon transistor is at this stage almost complete, since it comprises a source and a drain made of doped silicon, a semiconductor channel made of very lightly doped silicon between the source and drain, and an insulated gate above the channel.

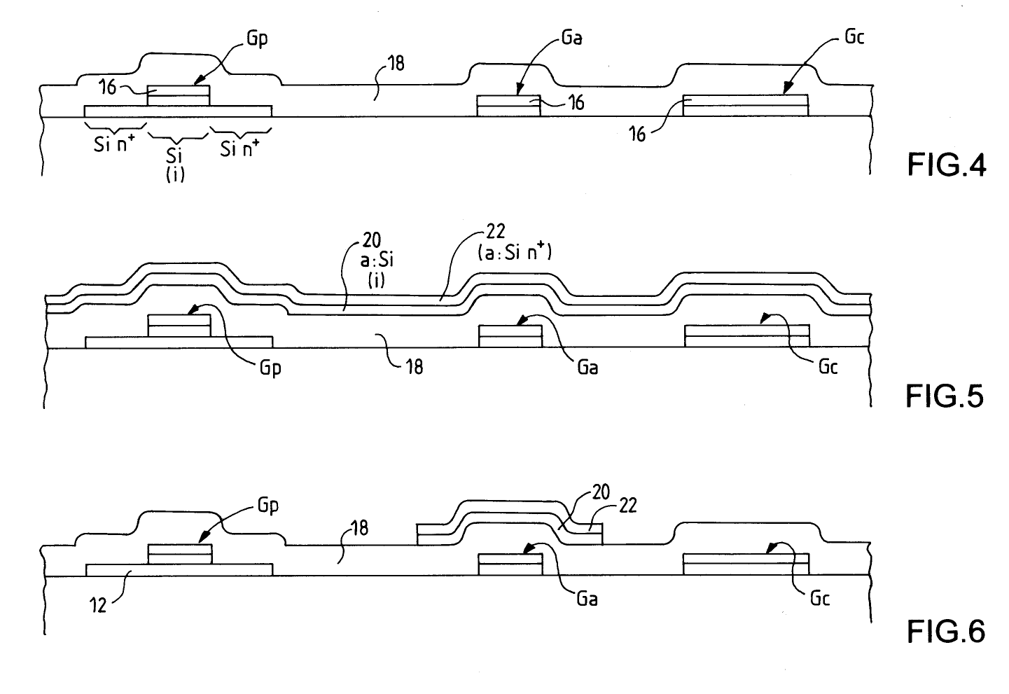

Next, (FIG. 4) a uniform insulation layer 18 (second insulating layer) is deposited, this layer covering the polycrystalline silicon transistor with its gate Gp and covers the gate Ga and the electrode Gc. The insulation layer 18 serves as protection (passivation) layer for the polycrystalline silicon transistor and serves as gate insulation layer (between gate and channel) for the amorphous silicon transistor. It also serves as dielectric for the capacitor of the zone Zc. The layer 18 may be made of silicon nitride or silicon oxide, or a combination of the two, for example with a thickness of about 300 nanometers.

After this step, there are several ways of continuing the fabrication, and these three ways start with a group of four operations which do not all necessarily follow one another in the order indicated in this paragraph: these four operations comprise the deposition of an intrinsic or lightly doped amorphous silicon layer; the etching of this layer in a zone extending beyond either side of the gate Ga of the amorphous transistor; the deposition of a more heavily doped amorphous silicon layer; and the opening of vias right through the thickness of the second insulating layer 18.

### First Method of Implementation (FIGS. 5 to 9)

In FIG. 5, a first layer 20 of very lightly doped amorphous silicon, or even intrinsic or quasi-intrinsic amorphous silicon (i-a:Si), is deposited uniformly on the insulator layer 18. This deposition is followed by deposition of a layer 22 of n-doped silicon (n⁺-a:Si). In practice, the amorphous silicon deposition is continued in the same frame, by adding an n-type impurity (arsenic) to the precursor gases.

Next, these two layers 22 and 20 are etched in succession using a third mask, the pattern of which defines a silicon island corresponding to the amorphous silicon transistor. The two layers are etched with a substance that etches silicon but does not etch the insulator 18, or only slightly. The doped silicon and the amorphous silicon may be etched in succession using two different etchants, the first for doped silicon and the second for intrinsic silicon. FIG. 6 shows the substrate at this stage, with a silicon island (lightly doped amorphous silicon coated with a more highly doped amorphous silicon) above the gate Ga extending sufficiently beyond either side of the gate so that it can constitute a source and a drain on either side of the gate. At this stage, the amorphous silicon transistor has not been produced since the doped silicon layer is uniform in the entire island: there is not yet a channel.

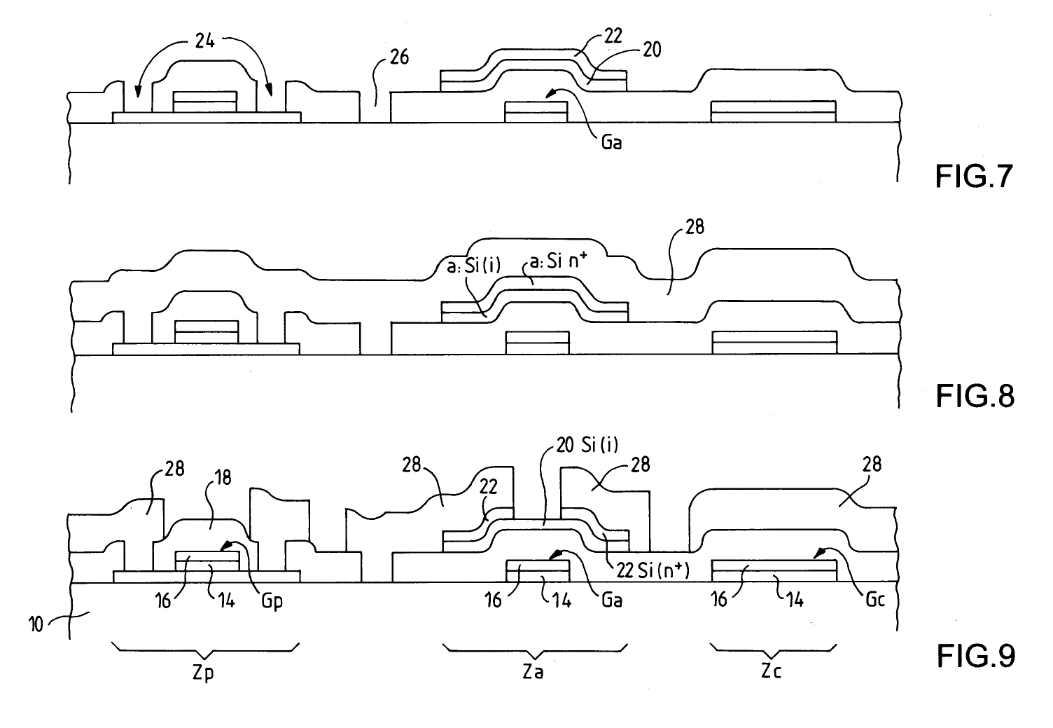

The next operation (FIG. 7) consists in opening vias 24 in the insulation layer 18, over the entire thickness of the latter, mainly in order to bare contact pads on the source and drain of the polycrystalline silicon transistor. This operation is also profitably used to open vias 26 in the form of isolation trenches at the points where the insulator covers the substrate 10 directly. These trenches may for example completely surround each of the amorphous transistors in order to isolate them from the other transistors. The purpose of this is to prevent current from leaking through the insulator of one transistor to another. A single via 26 has been shown in FIG. 7 to simplify the figure. A fourth mask is used for this operation.

Next (FIG. 8), a second conducting layer 28, in principle a metal, for example molybdenum, layer, is uniformly deposited with a thickness of about 300 nanometers.

The material deposited fills the vias 24 and 26 open in the insulator 18 and comes into contact with the source and drain of the polycrystalline silicon transistor of the zone Zp. It also comes into contact with the doped silicon layer 22 over the entire area of the latter, that is to say over the entire area corresponding to the amorphous silicon transistor.

The next step (FIG. 9) consists in etching the metal layer 28 through a fifth mask, in order to define the various interconnects useful for the circuit. Typically, the source contact is separated from the drain contact of each transistor, whether this is made of amorphous silicon or polycrystalline silicon—the layer above the gate Gp and above the gate Ga is therefore removed. In contrast, the conducting layer 28 above the electrode Gc is retained so as to form the second electrode of the capacitor of the zone Zc, separated from the first electrode by the insulator 18.

Finally, the last step (FIG. 9 again) consists in forming the channel of the amorphous transistor by removing the n⁺-doped silicon layer 22 at the point where it is not protected by the conducting layer, i.e. above the gate Ga of the amorphous silicon transistor. This removal takes place by selective chemical etching using an etchant that etches n⁺-doped silicon more rapidly than intrinsic silicon. This makes it possible to retain only the intrinsic amorphous silicon layer 20 above the gate Ga. It is this layer that serves as lightly doped semiconductor channel between two n⁺-doped silicon zones covered with metal 28, which form a source and a drain for the transistor. The gate Ga is located beneath this channel, and the insulator 18 serves as gate insulator for the amorphous silicon transistor which is now complete.

The entire circuit was produced using five masks if the polycrystalline silicon transistors are all of a single type. If nMOS and pMOS transistors have to be provided on the same substrate, an additional mask must be used, but this is a mask that does not need to be of great precision (overall masking of p-type transistors during n-type implantation and complementary overall masking of n-type transistors during p-type implantation).

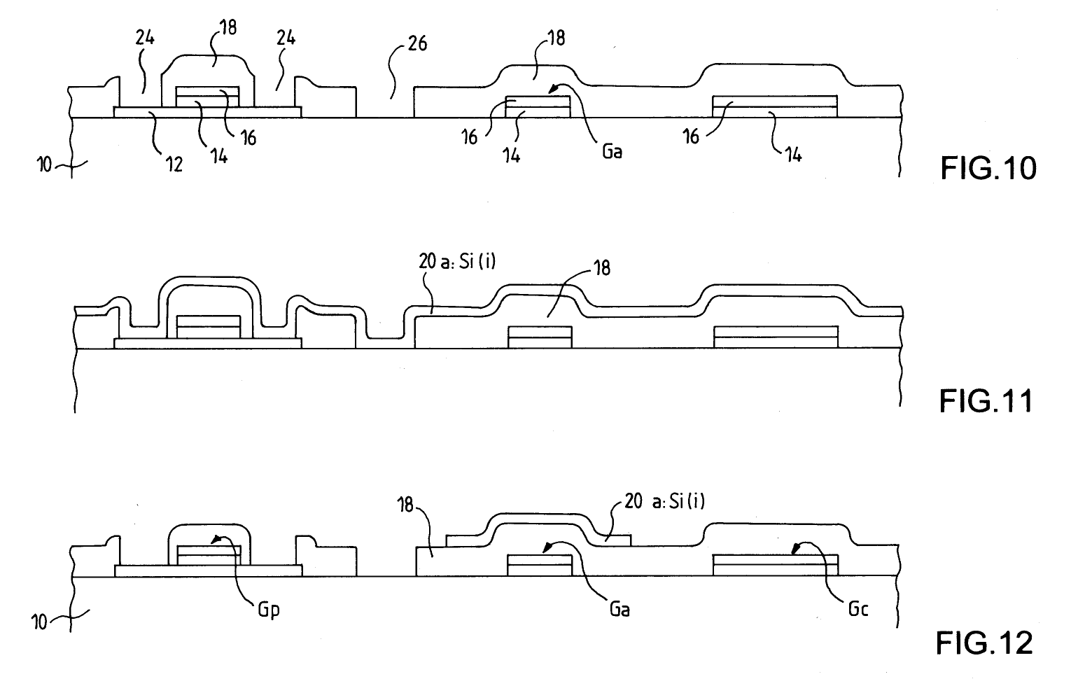

### Second Method of Implementation (FIGS. 10 to 14)

Starting from FIG. 4, and instead of continuing with the double silicon deposition of FIG. 5, this method now begins with the operation consisting in etching the vias 24 and 26 in the insulating layer 18. The vias are at the same places—they define the areas where it will be subsequently desired to pierce or interrupt the insulating layer so as to replace it with a conducting layer. The vias 24 define areas of contact with the source and the drain of the polycrystalline silicon transistor of the zone Zc and the vias 26 define the isolation trenches between transistor (FIG. 10). The mask used in this masking operation is a mask similar to the fourth mask of the first method of implementation.

Next (FIG. 11), the very lightly doped or intrinsic amorphous silicon (i-a:Si) 20 is deposited, but deposition does not continue with doped silicon.

On the contrary, the amorphous silicon is etched through a mask, which is similar to the third mask of the first method of implementation, in order to define silicon islands that correspond to the amorphous silicon transistor to be produced (FIG. 12). The

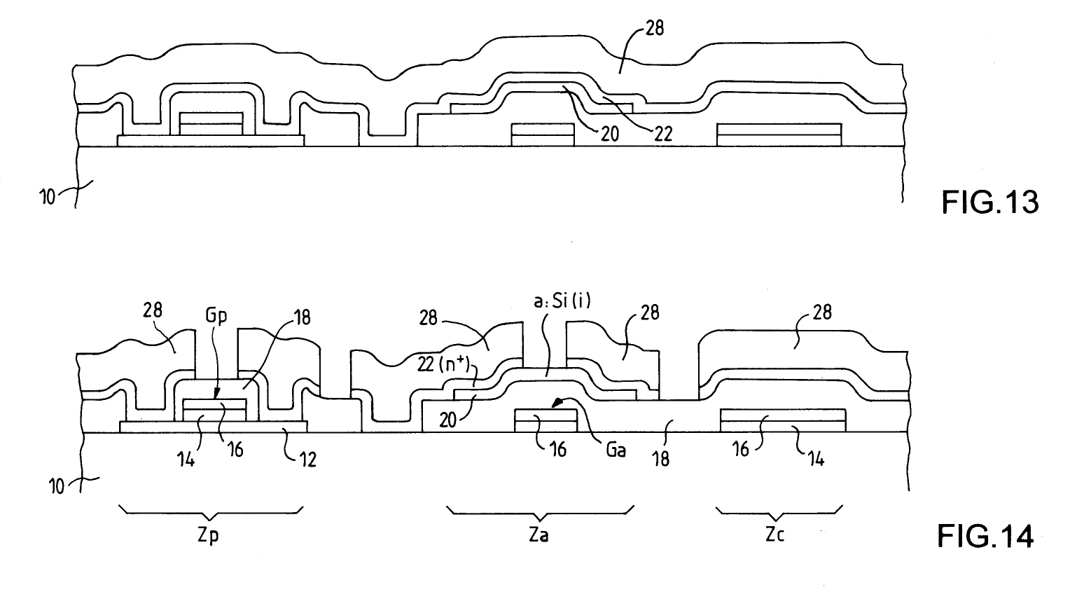

It is only at this stage that the n-doped amorphous silicon is deposited in the form of a uniform n⁺-a:Si layer 22, and this deposition is followed by the deposition of the second metal, for example molybdenum, conducting layer 28 (FIG. 13).

Next, the metal layer 28 is etched, through a fifth mask (the same as in the first method of implementation), in the pattern of interconnects to be produced, by removing this layer notably above the gate Gp of the polycrystalline silicon transistor and above the gate Ga of the amorphous silicon transistor. Said metal layer is not removed from above the electrode Gc of the capacitor. Thus, source contacts and drain contacts for all the transistors, upper capacitor electrodes and interconnects are defined (FIG. 14).

The final step (FIG. 14 again) consists in removing the n-doped silicon everywhere it is no longer protected by the second conducting layer, i.e. above the gate Gp, above the gate Ga and in all the areas that do not correspond to a circuit interconnect. The doped silicon of the layer 22 remains at the point where it is covered by the second conducting layer 28.

The removal of the doped silicon must, here again, take place using a selective etchant that does not etch, or hardly etches, the undoped amorphous silicon layer 20 at the point where it is present (zone Za) and not protected by the second conducting layer 28.

The undoped amorphous silicon layer that remains above the gate Ga constitutes the semiconductor channel of the amorphous silicon transistor between an n⁺-type source and an n⁺-type drain (layer 22). This transistor has its gate located beneath the channel, and the insulator 18 is the gate insulator.

It should be noted that it in this method of implementation it is unnecessary to dope the silicon of the island 12 on either side of the gate Gp in the step shown in FIG. 3, whereas this operation was necessary in the first method of implementation. In the second method, it may be seen from FIGS. 13 and 14 that it is possible to use the doping of the silicon of the layer 22 as dopant source for the source and the drain of the polycrystalline silicon transistor, since the layer 22 is in contact with the source and the drain, something which is not the case in the first method of implementation.

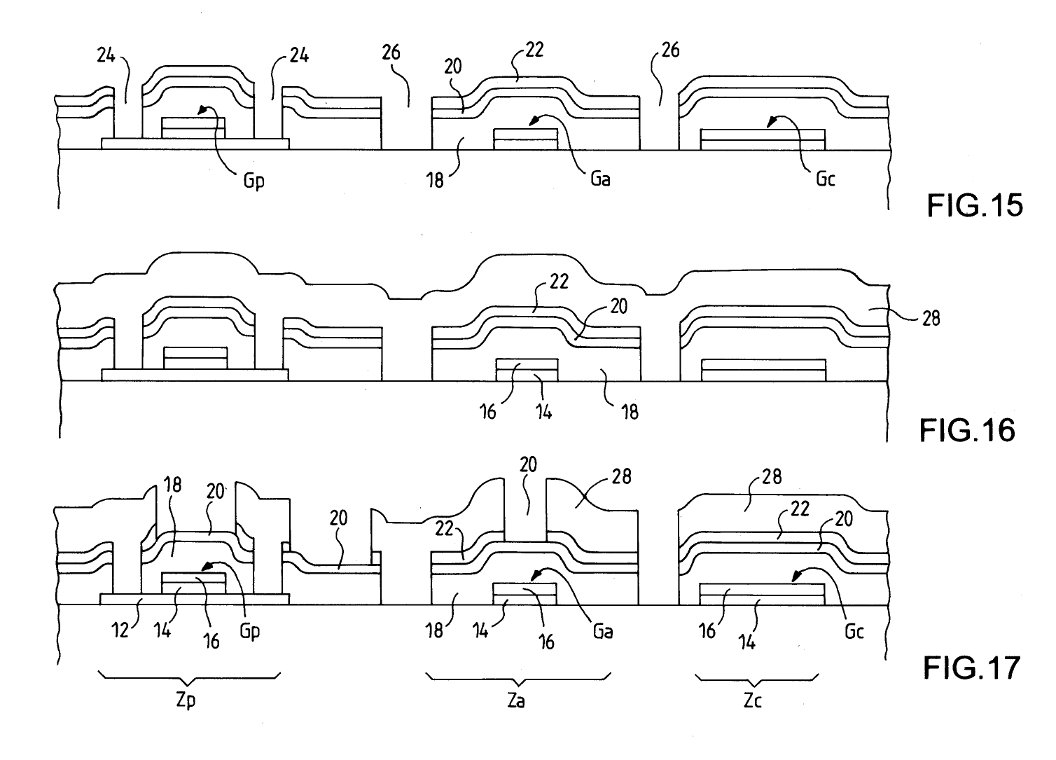

### Third Method of Implementation (FIGS. 15 to 17)

This starts from FIG. 5, which is therefore common to the first and the third methods of implementation, in which two silicon layers are deposited: a very lightly doped or undoped amorphous silicon (i-a:Si) layer 20 followed by an n-doped silicon (n⁺-a:Si) layer 22.

However, instead of etching the silicon layers 20 and 22 through a third mask and etching the second insulating layer 18 through a fourth mask, a single masking step is carried out in order to etch all these layers in the same pattern (FIG. 15).

This mask therefore defines both:

the islands corresponding to the amorphous silicon transistors that it is desired to produce; and

the vias in the second insulating layer 18, whether these be source and drain contact vias 24 for the polycrystalline silicon transistor or trench vias 26 surrounding each amorphous silicon transistor island. The silicon of the layers 20 and 22 remains both on the islands corresponding to the amorphous silicon transistors and in all the areas that are not vias.

FIG. 15 shows a trench 26 on each side of the amorphous silicon transistor since in this case it is necessary to have a trench completely around the island defining this transistor, unlike in the first two methods of implementation in which the trenches 26 and the semiconductor islands of amorphous transistors could be defined separately.

The next step consists in uniformly depositing the second conducting layer 28 (FIG. 16), which fills the vias and comes into contact with the source and drain of the polycrystalline transistor but also with the future source and drain of the amorphous transistor.

Next (FIG. 17), the metal layer 28 is etched in the pattern of interconnects to be produced, by removing this layer notably above the gate Gp of the polycrystalline silicon transistor and above the gate Ga of the amorphous silicon transistor. Said metal layer is not removed from above the electrode Gc of the capacitor. Thus, source contacts and drain contacts for all the transistors, upper capacitor electrodes and interconnects are defined.

It will be noted that the upper electrode of the capacitor of the zone Zc rests on the silicon double layer 20, 22, which itself rests on the dielectric formed by the insulating layer 18.

The final step (FIG. 17 again) consists in removing the n-doped silicon from everywhere it is no longer protected by the second conducting layer, i.e. above the gate Gp, above the gate Ga and in all the areas that do not correspond to a circuit interconnect. The doped silicon of the layer 22 remains at the point where it is covered by the second conducting layer 28.

The removal of the doped silicon must, here again, take place using a selective etchant that does not etch, or hardly etches, the undoped amorphous silicon layer 20 at the point where it is present (zone Za) and not protected by the second conducting layer 28.

The undoped amorphous silicon layer that remains above the gate Ga constitutes the semiconductor channel of the amorphous silicon transistor, between an n⁺-type source and an n⁺-type drain, and this transistor has its gate located beneath the channel and the insulator 18 is the gate insulator.

Finally, it should be noted that in this third method of implementation, amorphous silicon remains above the passivation layer 18 of the polycrystalline silicon transistor, between the source and drain contacts.

This solution assumes that the amorphous silicon of the layer 20 is very lightly doped so that there is not the least possibility of currents leaking into this layer between the source and the drain of the polycrystalline silicon transistor. If there is a fear of such leakage currents, it would be necessary to remove this amorphous silicon portion, either after this step or after or before the step shown in FIG. 15, which requires a mask for protecting the zone Zc at least during this removal step.

Three possible examples of how the invention may be implemented have thus been described. The invention is most particularly applicable to a display having at least one amorphous silicon transistor in each pixel and having polycrystalline silicon transistors serving for driving the rows of the display. Liquid crystal displays (LCDs) or light-emitting diode (LED or OLED) displays may advantageously use the invention.

The invention is also applicable to the transistors within one and the same pixel when the pixel comprises two transistors, one of which is preferably made of amorphous silicon because it must retain as much as possible of the charge stored on a capacitor throughout a duration of a frame, and the other of which is made of polycrystalline silicon because it must deliver a very constant or higher current.

This is the case for example for a pixel having two transistors arranged in the following manner: the first transistor has its gate connected to a row select conductor, its drain connected to a column conductor, which applies a potential corresponding to the data to be displayed, and its source connected to the gate of the second transistor. The second transistor has its drain raised to a supply potential, its source connected to a light-emitting diode which is also connected to ground. A storage capacitor is connected between the source of the first transistor and ground. To turn the diode on, the storage capacitor maintains a sufficient level of potential during a frame to turn the second transistor on. The second transistor delivers to the diode the constant current needed to turn the diode on. The first transistor is therefore made of amorphous silicon while the second is made of polycrystalline silicon. The storage capacitor is formed by the first conducting layer that forms the gates of the two transistors, by the insulating layer that forms the gate insulator of the amorphous silicon transistor, and by the second conducting layer that the source and drain contacts of the two transistors.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. A process for fabricating thin-film transistors made of amorphous silicon and polycrystalline silicon on one and the same substrate, comprising the steps of
a) first forming a polycrystalline silicon island corresponding to a polycrystalline silicon transistor on the substrate;
b) then depositing a first electrically insulating layer and a first conducting layer;
c) etching the insulating layer and the conducting layers to the same pattern so as to simultaneously define, in the first conducting layer, a first insulated gate (Gp) on top of the island and a second gate (Ga) away from the island;
d) depositing a second insulating layer, which forms a passivation layer on top of the first insulated gate and forms the gate insulator on top of the second gate; and then
fabricating the amorphous silicon transistor continues with steps comprising, depositing intrinsic amorphous silicon in order to constitute the channel of the amorphous silicon transistor on top of the second gate, depositing doped amorphous silicon in contact with the intrinsic amorphous silicon everywhere the latter is present, in order to define a source and a drain on either side of this channel of the amorphous silicon transistor, depositing on the doped amorphous silicon layer of a second conducting layer with contacts on the sources and drains of the various transistors, etching the second conducting layer and removing the subjacent doped amorphous silicon layer, where the latter has not been protected by the second conducting layer, using a selective etchant that hardly etches the intrinsic amorphous silicon.

2. The process as claimed in claim 1, wherein the deposition of the doped amorphous silicon layer is carried out immediately after the deposition of intrinsic amorphous silicon, and then these two layers are etched in one and the same pattern defining an island corresponding to the amorphous transistor, and finally vias are etched in the second insulating layer.

3. The process as claimed in claim 1, wherein, after step d, vias are etched in the second insulating layer, the layer of intrinsic amorphous silicon is then deposited, this layer is then etched in order to keep it in a zone extending beyond either side of the gate of the amorphous transistor, and then doped amorphous silicon and the second conducting layer are deposited.

4. The process as claimed in claim 1, wherein, after step d, the intrinsic amorphous silicon is firstly deposited, then immediately afterwards doped amorphous silicon is deposited, and then these two layers and the second insulating layer are etched together so as to open vias passing through the three layers.

5. The process as claimed in claim 1, wherein the initial deposition of polycrystalline silicon comprises the deposition of amorphous silicon followed by laser recrystallization.

6. The process as claimed in claim 1, wherein, after step c), the polycrystalline silicon is doped, at the point where it has not been protected by the gate, by means of an ion implantation of impurities corresponding to the type of transistor—NMOS or pMOS—to be produced.

7. A thin-film circuit comprising, on one and the same substrate, at least two thin-film transistors, one of which is a polycrystalline silicon transistor with a gate (Gp) above the channel and the other is an amorphous silicon transistor with a gate (Ga) beneath the channel, the gates of the two transistors being formed by two portions of one and the same conducting layer, one portion being deposited on top of a polycrystalline silicon island, from which it is separated by a first insulating layer portion, and the other portion being deposited on top of the substrate, from which it is separated by a second portion of the same insulating layer, wherein the circuit includes rows and columns of display pixels, with at least one amorphous silicon transistor and at least one polycrystalline silicon transistor in each pixel, the amorphous silicon transistor having its gate connected to a row select conductor, its drain connected to a column conductor, which applies a potential corresponding to the data to be displayed, and its source connected to the gate of the second transistor, the polycrystalline silicon transistor having its drain raised to a supply potential, its source connected to a light-emitting diode which is also connected to ground, and a storage capacitor being connected between the source of the amorphous silicon transistor and ground, the storage capacitor being produced by the conducting layer that forms the gates of the two transistors, by the insulating layer that forms the gate insulator of the amorphous silicon transistor, and by a second conducting layer that also forms the source and drain contacts of the two transistors.

8. The process as claimed in claim 2, wherein the initial deposition of polycrystalline silicon comprises the deposition of amorphous silicon followed by laser recrystallization.

9. The process as claimed in claim 3, wherein the initial deposition of polycrystalline silicon comprises the deposition of amorphous silicon followed by laser recrystallization.

10. The process as claimed in claim 4, wherein the initial deposition of polycrystalline silicon comprises the deposition of amorphous silicon followed by laser recrystallization.

11. The process as claimed in claim 2, wherein, after step c), the polycrystalline silicon is doped, at the point where it has not been protected by the gate, by means of an ion implantation of impurities corresponding to the type of transistor—nMOS or pMOS—to be produced.

12. The process as claimed in claim 3, wherein, after step c), the polycrystalline silicon is doped, at the point where it has not been protected by the gate, by means of an ion implantation of impurities corresponding to the type of transistor—nMOS or pMOS—to be produced.

13. The process as claimed in claim 4, wherein, after step c), the polycrystalline silicon is doped, at the point where it has not been protected by the gate, by means of an ion implantation of impurities corresponding to the type of transistor—nMOS or pMOS—to be produced.

14. The process as claimed in claim 5, wherein, after step c), the polycrystalline silicon is doped, at the point where it has not been protected by the gate, by means of an ion implantation of impurities corresponding to the type of transistor—nMOS or pMOS—to be produced.
